(19) United States
(12) Patent Application Publication
(10) Pub. No.: US 2024/0194549 A1
(43) Pub. Date: Jun. 13, 2024

(54) SEMICONDUCTOR DEVICE ASSEMBLIES WITH AN ENCAPSULANT MATERIAL HAVING ENHANCED THERMAL CONDUCTIVITY, AND METHODS FOR MAKING THE SAME

(71) Applicant: Micron Technology, Inc., Boise, ID (US)

(72) Inventors: Min Hua Chung, Taichung (TW); Chong Leong Gan, Taichung (TW)

(21) Appl. No.: 18/505,928

(22) Filed: Nov. 9, 2023

Related U.S. Application Data
(60) Provisional application No. 63/431,965, filed on Dec. 12, 2022.

(51) Int. Cl. H01L 23/29; H01L 21/56

(52) U.S. Cl. CPC H01L 23/295; H01L 21/56

(57) ABSTRACT

A semiconductor device assembly is provided. The assembly includes a support layer with an inside surface, a semiconductor device, and an encapsulant material. The encapsulant material includes a bulk material and thermally conductive nanoparticles, each nanoparticle having an electrically insulative shell and an electrically conductive core. The semiconductor device is disposed on the inside surface of the support layer, the thermally conductive nanoparticles are evenly distributed throughout the bulk material, and the encapsulant material at least partially encapsulates the semiconductor device.

### CROSS-REFERENCE TO RELATED APPLICATION(S)

The present application claims priority to U.S. Provisional Patent Application No. 63/431,965, filed Dec. 12, 2022, the disclosure of which is incorporated herein by reference in its entirety.

### TECHNICAL FIELD

The present disclosure generally relates to semiconductor device assemblies, and more particularly relates to semiconductor device assemblies with an encapsulant material having enhanced thermal conductivity, and methods for making the same.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 is a simplified schematic cross-sectional view of an example semiconductor device assembly with embodiments of the present technology.

FIG. 2 is a detail cross-sectional view of an encapsulant material in accordance with embodiments of the present technology.

FIG. 3 is a simplified schematic cross-sectional view of a semiconductor device assembly in accordance with embodiments of the present technology.

FIG. 4 is a simplified schematic cross-sectional view of a semiconductor device assembly in accordance with embodiments of the present technology.

FIG. 5 is a simplified schematic cross-sectional view of a semiconductor device assembly in accordance with embodiments of the present technology.

FIG. 6 is a simplified schematic cross-sectional view of a semiconductor device assembly in accordance with embodiments of the present technology.

FIG. 7 is a schematic view illustrating a process of making thermally conductive nanoparticles in accordance with embodiments of the present technology.

FIG. 8 is a schematic view showing a system that includes a semiconductor device assembly configured in accordance with an embodiment of the present technology.

FIG. 9 is a flow chart illustrating a method of making a semiconductor device assembly in accordance with an embodiment of the present technology.

### DETAILED DESCRIPTION

The electronics industry relies upon continuous innovation in the field of semiconductor packaging to meet the global need for higher-functioning technology. Future 5G, 6G, AI, and Autonomous chips require a higher density of semiconductor devices within a single package, as well as higher integrated memory bandwidth. These packages produce a very high amount of heat that reduce the lifespan and efficiency of the devices contained within.

One way of dealing with this high amount of heat are encapsulation materials with high thermal conductivity for better thermal management. Highly thermally conductive materials, however, have disadvantages. Most highly thermally conductive materials are also highly electrically conductive. This electrical conductivity is anathema to an encapsulation material, in that it would allow for dielectric breakdowns between devices in the package at relatively low voltages. These breakdowns would result in random behavior from the devices as signals are lost or received at the wrong locations, as well as damage to the devices and the package itself.

To address these drawbacks and others, various embodiments of the present disclosure provide semiconductor device assemblies with an encapsulant material having enhanced thermal conductivity.

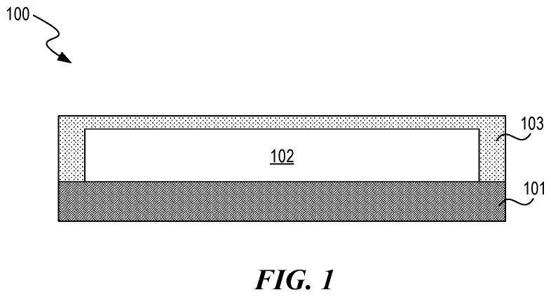

FIG. 1 is a simplified schematic cross-sectional view of a semiconductor device assembly with an encapsulant material having enhanced thermal conductivity 100, in accordance with embodiments of the present technology. The assembly 100 includes a support layer 101 with an inside surface where a semiconductor device 102 is disposed. At least partially encapsulating the semiconductor device 102 is an encapsulant material having enhanced thermal conductivity 103.

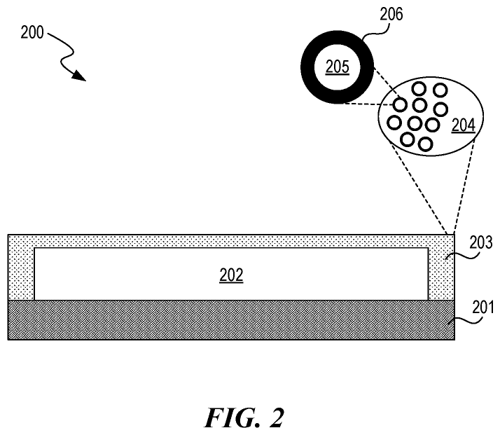

FIG. 2 is a detail cross-sectional view of an encapsulant material having enhanced thermal conductivity 203 in accordance with embodiments of the present technology. The encapsulant material 203 at least partially encapsulates a semiconductor device 202 disposed on an inside surface of a support layer 201 as part of an assembly 200. The semiconductor device can be a NAND Flash memory chip, a DRAM chip, a graphics processing unit, a light-emitting diode, a transistor, etc., while the support layer can be a substrate, a section of a reconstituted wafer, etc. The encapsulant material 203 includes thermally conductive nanoparticles disposed in a bulk material 204 (e.g., an encapsulating mold compound or the like). Each nanoparticle includes an electrically insulative shell 206 surrounding an electrically conductive core 205. The electrically insulative shell 206 can be silica. The electrically conductive core can be one of the following: Copper, Silver, Gold, or alloys thereof, or Carbon Nanotubes or Graphene fragments.

As part of the encapsulation material, the bulk material itself can include a resin and a hardening agent. This resin can be derived from a variety of sources, which can include a polyester resin, a phenolic resin, an alkyd resin, a polycarbonate resin, a polyamide resin, a polyurethane resin, a silicone resin, an epoxy resin, etc. The hardening agent, or curing agent as it may also be called, can include one of a variety of aliphatic amine curing agents, one of a variety of cycloaliphatic amine curing agents, one of a variety of polyvalent phenols such as phenol novolak, aralkylphenol novolak, and the like, acid anhydrides such as pyromerit anhydride, trimerit anhydride, benzophenonetetr acarboxylic acid anhydride and the like, etc.

Within the nanoparticles themselves, the core and shell can have distinct sizes. The electrically conductive core 205 can have a size of one hundred nanometers to two hundred and fifty nanometers. The core can also have a size of two hundred and fifty nanometers to five hundred nanometers; a size of five hundred nanometers to seven hundred and fifty nanometers; or a size of seven hundred and fifty nanometers to one micrometer. Each electrically insulative shell 206 can have a thickness of one hundred nanometers to five hundred nanometers. Additionally, these shells 206 can have a thickness of five hundred nanometers to one micrometer; a thickness of one micrometer to five micrometers, or a thickness of five micrometers to ten micrometers. The total size of a thermally conductive nanoparticle, inclusive of the shell, can be two hundred nanometers to seven hundred and fifty nanometers across, or it can be seven hundred and fifty nanometers across to three micrometers across, or it can be three micrometers to eleven micrometers across.

The disclosed encapsulant material can form part of the packaging for various high-performances assemblies. Such assemblies are labeled “high-performance” for their increased demands in terms of power and speed, which produce greater amounts of heat. Due to the properties of its thermally conductive nanoparticles, the disclosed encapsulant material's ability to conduct heat from the assembly (without compromising electrical insulation) enables new embodiments of these “high-performance” assemblies to exist.

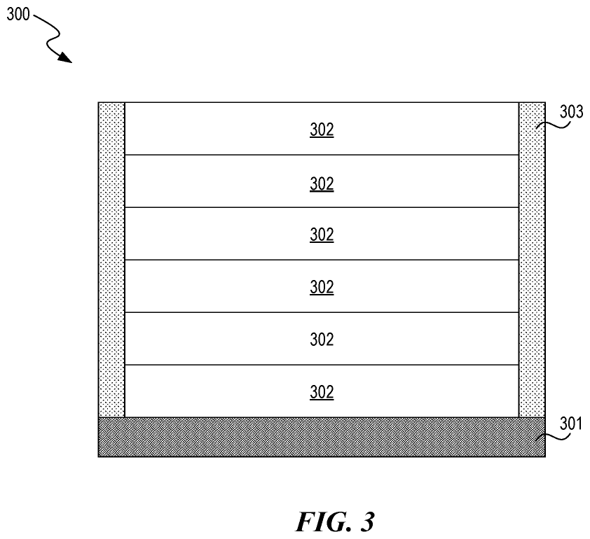

FIGS. 3-6 are simplified schematic cross-sectional views of such “high-performance” semiconductor device assemblies.

FIG. 3 illustrates a High-bandwidth memory assembly 300, which can be one example of a “high-performance” semiconductor device assembly that can include the disclosed encapsulation material 303 surrounding a stack of semiconductor devices 302, which in this potential embodiment, can be a stack of DRAM memory die connected by Through Silicon Vias to a High Bandwidth Memory controller die as a support layer 301.

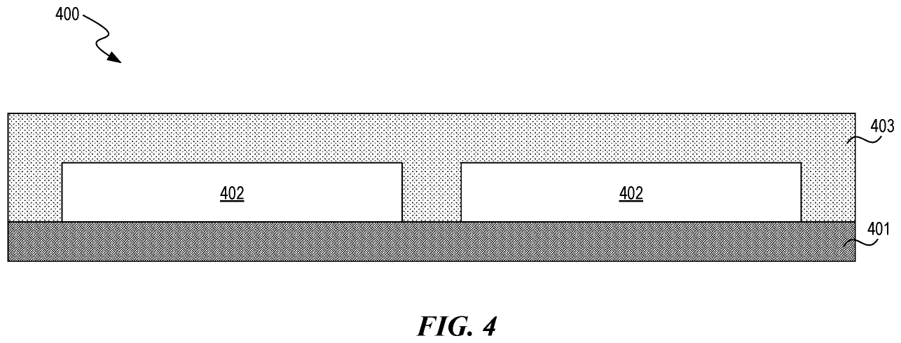

In FIG. 4, a Graphics assembly 400 is illustrated, which depicts another potential “high-performance” embodiment of the disclosed assembly. This assembly 400 can include the disclosed encapsulation material 403, along with semiconductor devices 402 that—in this potential embodiment—includes a heat sink, a Video BIOS, a Video Memory chip, and a graphics processing unit. The support layer 401 in this embodiment is a non-metallic substrate, which can be made with fiberglass filaments and epoxy.

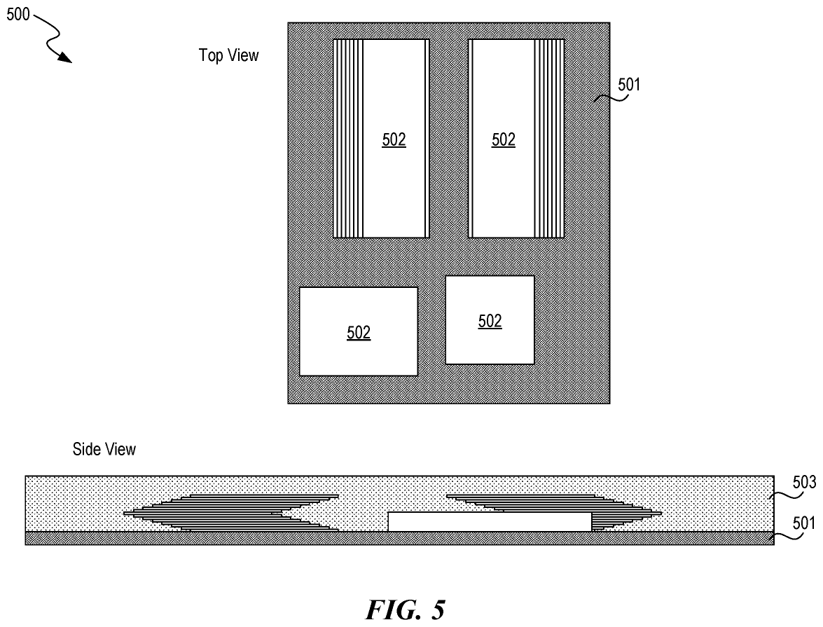

Another potential “high-performance” embodiment is illustrated in FIG. 5. This assembly 500 is a Solid-State Drive. The Solid State Drive can include a ball grid array, flash memory, DRAM, 3D XPoint, or a hybrid of spinning disks and flash memory as its semiconductor devices 502, encapsulated by the disclosed encapsulation material 503 and resting atop an electrically insulative substrate 501.

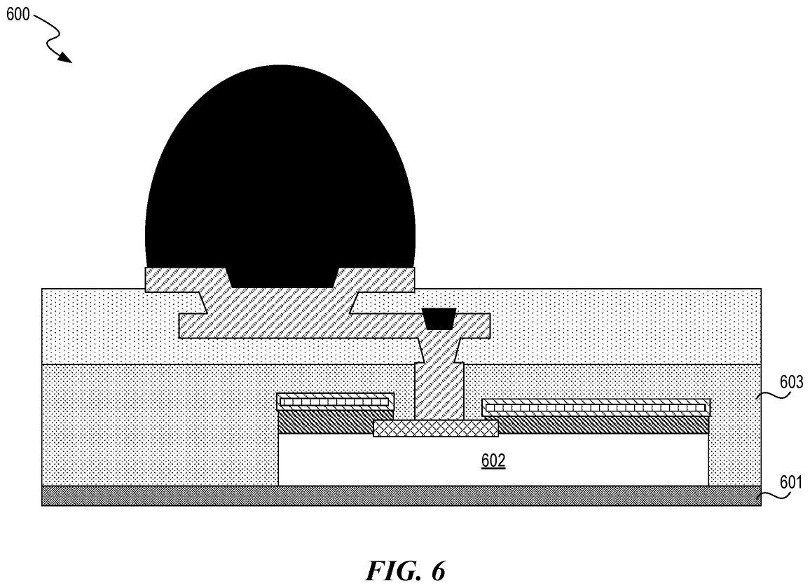

As a final example of a “high-performance” assembly which can include the disclosed encapsulation material, FIG. 6 illustrates a Fan-out chip-scaled assembly 600 in which the support layer is a Redistribution Layer 601, the semiconductor device is embedded entirely within the disclosed encapsulation material 603, and a series of solder balls, Through Silicon Vias, and substrate traces connect to the device 602.

The foregoing figures exhibit a variety of potential form factors and packaging types the disclosed encapsulant material can be included within. The disclosed encapsulant material can at least partially encapsulate semiconductor devices formed into stacks connected with through silicon vias, or stacked as shingles and connected with wire bonds, or embedded within various other layers of the assembly.

The foregoing assemblies can have an allowable junction temperature of ten degrees Celsius. For an encapsulant material with a greater thermal conductivity, measured in Watts per meter-Kelvin (W/mK), an assembly can have thinner semiconductor die, measured in nanometers (um), as well as higher power, measured in Watts, directed to it without exceeding the allowable junction temperature.

A realistic estimate of the thermal conductivity afforded by the disclosed encapsulant material is greater than four Watts per meter-Kelvin. This estimated thermal conductivity would enable the foregoing assemblies to have semiconductor die with a thickness of one-hundred fifty micrometers or less as well as a power measuring up to and in excess of ten Watts directed to it without the assembly exceeding the allowable junction temperature. By allowing an assembly to conduct more heat, the disclosed encapsulant material can allow such assemblies to operate at increased speeds, and include thinner die, which would in turn allow more die to be included in such high-performance assemblies.

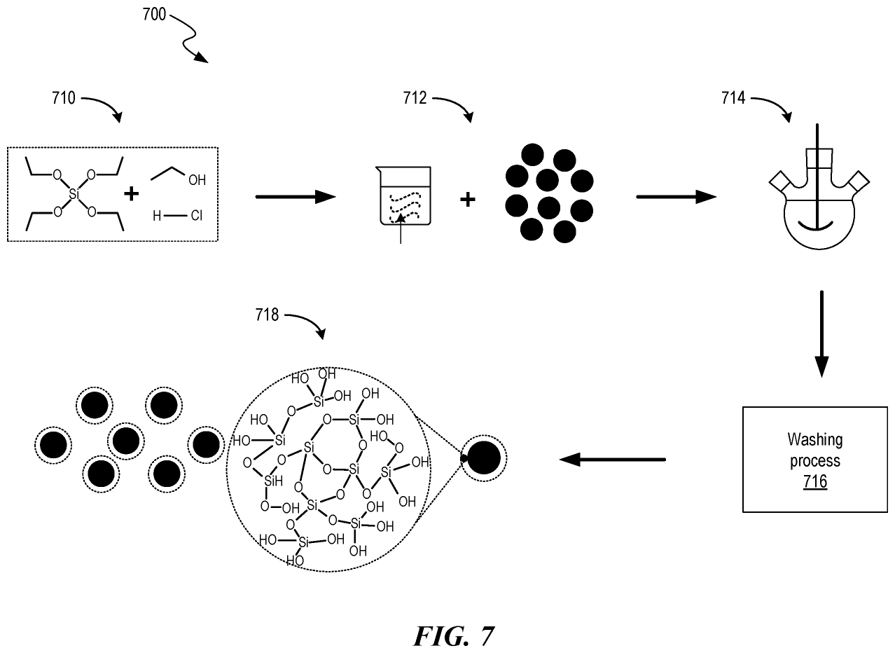

FIG. 7 is a schematic view illustrating a process of making thermally conductive nanoparticles, wherein each nanoparticle has an electrically insulative shell and an electrically conductive core, in accordance with embodiments of the present technology. The method 700 can begin by adding an ethyl silicate (e.g., TEOS) to an alcohol mixture and then adding hydrochloric acid as a catalyst, in a first step 710. This yields a solution which includes a solvent, a reaction medium, and electrically insulative particles (e.g., silica). Next, thermically conductive nanoparticles are added to the solution in a second step 712. These nanoparticles could be derived from a metal (e.g., Copper, Silver, Gold, or alloys thereof, etc.), Carbon Nanotubes, or Graphene fragments. They are added to the solution while stirring the solution, in a third step 714. After mixing, the solvent is gradually dissolved from the reaction medium to yield the thermally conductive nanoparticles, wherein each nanoparticle has an electrically insulative shell. These nanoparticles are then washed (e.g., with an alcohol) to remove an organic residue, in a fourth step 716. Finally, the nanoparticles are collected, in a fifth step 718.

These nanoparticles can then be mixed into a bulk material (e.g., an encapsulating mold compound or the like) so that the nanoparticles are distributed throughout the bulk material, as a method for creating an encapsulant material in accordance with embodiments of the present technology. The bulk material can further comprise a resin (e.g., a polyester resin, a phenolic resin, an alkyd resin, a polycarbonate resin, a polyamide resin, a polyurethane resin, a silicone resin, an epoxy resin, etc.) and a hardening agent (e.g., an aliphatic amine curing agents, a cycloaliphatic amine curing agents, a polyvalent phenols such as phenol novolak, aralkylphenol novolak, and the like, or an acid anhydrides such as pyromerit anhydride, trimerit anhydride, benzophenonetetr acarboxylic acid anhydride and the like, etc.).

Although in the foregoing example embodiment semiconductor device assemblies have been illustrated and described as including a single semiconductor device, in other embodiments assemblies can be provided with additional semiconductor devices. For example, the single semiconductor devices illustrated in FIGS. 1, 2, 4, 5, and/or 6 could be replaced with, e.g., a vertical stack of semiconductor devices, a plurality of semiconductor devices, mutatis mutandis.

In accordance with one aspect of the present disclosure, the semiconductor devices illustrated in the assemblies of FIGS. 1-6 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

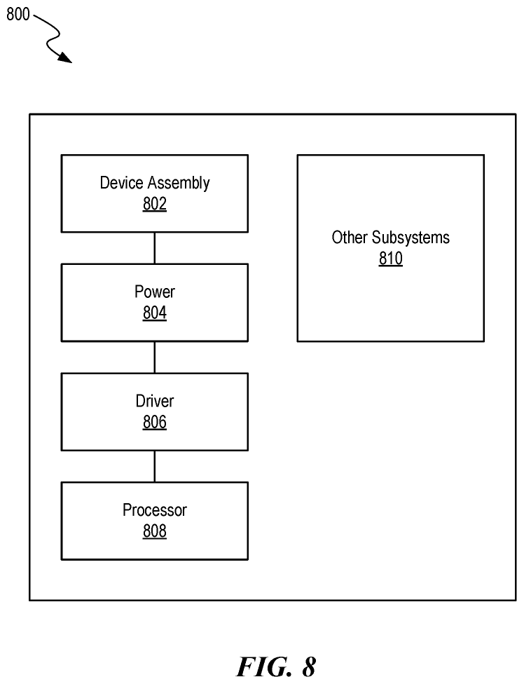

Any one of the semiconductor devices and semiconductor device assemblies described above with reference to FIG. 1-6 can be incorporated into any of a myriad of larger and/or more complex systems, a representative example of which is system 800 shown schematically in FIG. 8. The system 800 can include a semiconductor device assembly (e.g., or a discrete semiconductor device) 802, a power source 804, a driver 806, a processor 808, and/or other subsystems or components 810. The semiconductor device assembly 802 can include features generally similar to those of the semiconductor devices described above with reference to FIG. 1 and FIGS. 3-6. The resulting system 800 can perform any of a wide variety of functions, such as memory storage, data processing, and/or other suitable functions. Accordingly, representative systems 800 can include, without limitation, hand-held devices (e.g., mobile phones, tablets, digital readers, and digital audio players), computers, vehicles, appliances, and other products. Components of the system 800 may be housed in a single unit or distributed over multiple, interconnected units (e.g., through a communications network). The components of the system 800 can also include remote devices and any of a wide variety of computer readable media.

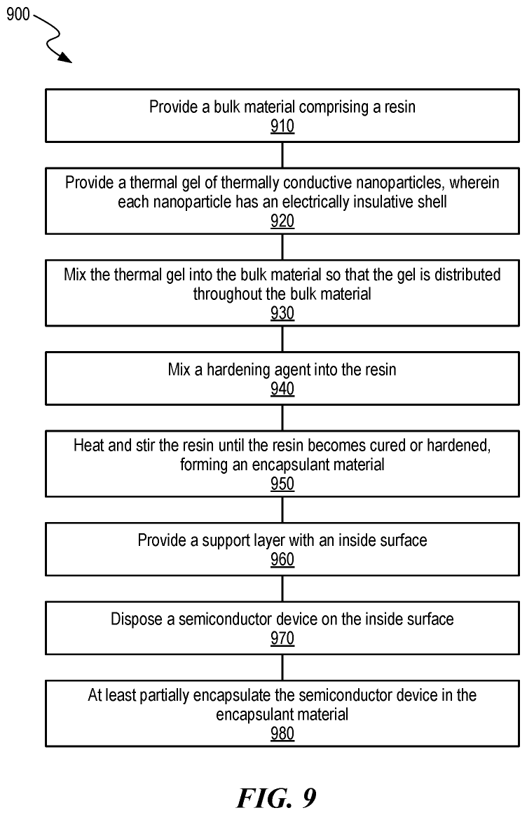

FIG. 9 is a flow chart illustrating a method of making a semiconductor device assembly with an encapsulation material having enhanced thermal conductivity. The method includes providing a bulk material comprising a resin (box 910). The method further includes providing a thermally conductive nanoparticles, wherein each nanoparticle has an electrically insulative shell and an electrically conductive core (box 920). The method further includes mixing the thermally conductive nanoparticles into the bulk material so that the nanoparticles are distributed throughout the bulk material (box 930). The method further includes mixing a hardening agent into the resin (box 940). The method further includes providing a support layer with an inside surface (box 950). The method further includes disposing a semiconductor device on the inside surface (box 960). The method further includes at least partially encapsulating the semiconductor device in the encapsulant material (box 970). The method further includes curing the encapsulant material to harden it (box 980).

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a support layer with an inside surface;
a semiconductor device disposed on the inside surface; and
an encapsulant material at least partially encapsulating the semiconductor device, including:
a bulk material, and
thermally conductive nanoparticles distributed through the bulk material, each nanoparticle having an electrically insulative shell and an electrically conductive core.

2. The semiconductor device assembly of claim 1, wherein the electrically insulative shell comprises silica.

3. The semiconductor device of claim 1, wherein the electrically conductive core comprises one of the following: Copper, Silver, Gold, or alloys thereof, or Carbon Nanotubes or Graphene fragments.

4. The semiconductor device assembly of claim 1, wherein the bulk material comprises a resin and a hardening agent.

5. The semiconductor device assembly of claim 1, wherein each electrically conductive core has a size ranging from one hundred nanometers to one micrometer.

6. The semiconductor device assembly of claim 1, wherein each electrically insulative shell has a thickness ranging from one hundred nanometers to ten micrometers.

7. The semiconductor device assembly of claim 1, wherein the encapsulant material further comprises a thermal conductivity greater than four Watts per meter-Kelvin.

8. The semiconductor device assembly of claim 1, wherein a power measuring in excess of ten Watts can be directed or applied to the assembly without the assembly exceeding an allowable junction temperature of ten degrees Celsius.

9. The semiconductor device assembly of claim 1, wherein the semiconductor die has a thickness of one-hundred fifty micrometers or less without the assembly exceeding an allowable junction temperature of ten degrees Celsius.

10. An encapsulant material, comprising:
a bulk material; and
thermally conductive nanoparticles distributed throughout the bulk material, each nanoparticle having an electrically insulative shell and an electrically conductive core.

11. The encapsulant material of claim 10, wherein the electrically insulative shell comprises silica.

12. The encapsulant material of claim 10, wherein the electrically conductive core comprises one of the following: Copper, Silver, Gold, or alloys thereof, or Carbon Nanotubes, or Graphene fragments.

13. The encapsulant material of claim 10, wherein the bulk material comprises a resin and a hardening agent.

14. The encapsulant material of claim 10, wherein each electrically conductive core has a size ranging from one hundred nanometers to one micrometer.

15. The encapsulant material of claim 10, wherein each electrically insulative shell has a thickness ranging from one hundred nanometers to ten micrometers.

16. The encapsulant material of claim 10, wherein the encapsulant material further comprises a thermal conductivity greater than four Watts per meter-Kelvin.

17. A method of making an encapsulant material, the method comprising:
providing a bulk material;
providing thermally conductive nanoparticles, each nanoparticle having an electrically insulative shell and an electrically conductive core;
mixing the thermally conductive nanoparticles into the bulk material so that the nanoparticles are distributed throughout the bulk material.

18. The method of claim 17, wherein the bulk material comprises a resin and a hardening agent.

19. The method of claim 17, wherein the method further comprises:
providing a support layer with an inside surface;
disposing a semiconductor device on the inside surface; and
at least partially encapsulating the semiconductor device in the encapsulant material.

20. The method of claim 18, wherein the method further comprises:
curing the bulk material to harden it.
